(19) United States
(12) Patent Application Publication
(10) Pub. No.: US 2003/0107390 A1
(43) Pub. Date: Jun. 12, 2003

(54) Structure of a wire clip for integrated circuit

(76) Inventors: Jui-Hsing Kuo, Taipei (TW); Jung-Ping Hsiao, Taipei (TW)

Correspondence Address: KUO, Jui-Hsing, PO Box 82-144, TAIPEI, TW

(21) Appl. No.: 10/274,925

(22) Filed: Oct. 22, 2002

(30) Foreign Application Priority Data
Dec. 7, 2001 (TW) 090221517

(51) Int. Cl. G01R 31/02

(52) U.S. Cl. 324/755

(57) ABSTRACT

An improved structure of wire clip for integrated circuit is disclosed. An improved structure of a wire clip for integrated circuit having a main body with the front end thereof being provided with a front wall and a rear wall, a spring plate elastically extended toward the rear wall being provided between the front wall and the rear wall, the front end of the spring plate being provided with an abrasion-resistant such that a passage is formed between the abrasion-resistant plate and the front wall, and the rear wall being provided with an adjusting bolt, and the top of the passage being provided with a wire mount, and the metallic wire passed through the wire mount and the passage, characterized in that the front wall of the main body having one end is mounted with a connection plate, and the bottom edge of the connection plate is provided with a blocking shaft such that the blocking shaft transversely crosses the bottom of the rear side of the passage thereby preventing wires from being entangled with each other.

### BACKGROUND OF THE INVENTION

(a) Field of the Invention

The present invention relates to an improved structure of a wire clip for integrated circuit, and in particular, a wire clip which prevents wires being entangled with each others.

(b) Description of the Prior Art

FIGS. 2 and 3 respectively show a perspective view and the front elevational view of a conventional wire clip. FIG. 4 is a sectional view along line I-I of FIG. 1. The conventional wire clip 20 having a front end provided with a front wall 21 and a rear wall 22. An elastic plate 23 extended toward the rear wall 22 is mounted between the front wall 21 and the rear wall 22. The front end of the elastic plate 23 is mounted with an abrasive resistant plate 24 such that a passage 25 is formed between the abrasive resistant plate 24 and the front wall 21. The rear wall 22 is mounted with an adjusting bolt 26. The rotation of the adjusting bolt 26 will urge the abrasive resistant plate 24 so as to change the gap of the passage 25. The top of the passage 25 can be mounted with a wire mount 27 such that the metallic wire 30 within the wire supplying device passes through the wire mount 27 and the passage 25. A solder gun will melt the metallic wire 30 and the wire 30 will be soldered on a determined position. The conventional clip 20 allows the metallic wire 30 to be rapidly and precisely melted and soldered onto the predetermined position, but the structure of this conventional clip 20 causes intermittent movement and the metallic wire 30 is often broken off and occasionally, the metallic wire 30 exceeds the range of the passage between the abrasion-resistant plate 24 and the front wall 21. Thus, wire entangling is frequently occurred and the entire operation will be stopped. FIG. 5 is another conventional wire clip which is used to mitigate the above drawback.

The rear section of the front wall 21 of the wire clip 20 is provided with a blocking bar 28 such that the passage 25 between the abrasion-resistant plate 24 and the front wall 21 is sealed so that the metallic wire 30 will not exceed the range of the passage 25, avoiding the wire entangling situation. However, the abrasion-resistant plate 24 is connected to the front end of the spring plate 23, when the adjusting bolt 26 is rotated to change the gap of the passage 25, or the pulling force of the metallic wire 30 is slightly larger, the metallic wire 30 will pass through the slit between the blocking bar 28 and the abrasion-resistant plate 24. At this instance, the user will spend more maintenance time to solve the wire entangling problem.

### SUMMARY OF THE INVENTION

Accordingly, it is an object of the present invention to provide an improved structure of a wire clip for integrated circuit which mitigates the above drawbacks.

An aspect of the present invention is to provide an improved structure of a wire clip for integrated circuit having a main body with the front end thereof being provided with a front wall and a rear wall, a spring plate elastically extended toward the rear wall being provided between the front wall and the rear wall, the front end of the spring plate being provided with an abrasion-resistant such that a passage is formed between the abrasion-resistant plate and the front wall, and the rear wall being provided with an adjusting bolt, and the top of the passage being provided with a wire mount, and the metallic wire passed through the wire mount and the passage, characterized in that the front wall of the main body having one end is mounted with a connection plate, and the bottom edge of the connection plate is provided with a blocking shaft such that the blocking shaft transversely crosses the bottom of the rear side of the passage.

The foregoing object and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 schematically shows the formation of integrated circuit.

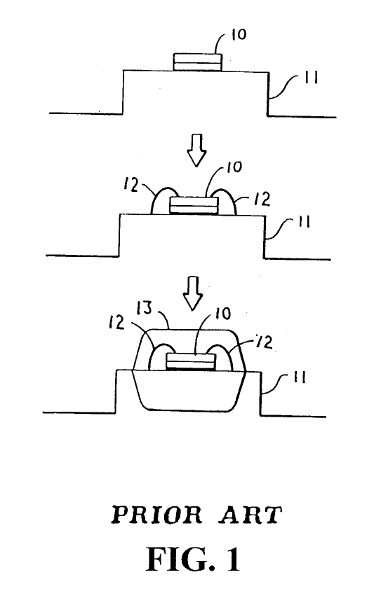

FIG. 2 is a perspective view of a conventional wire clip.

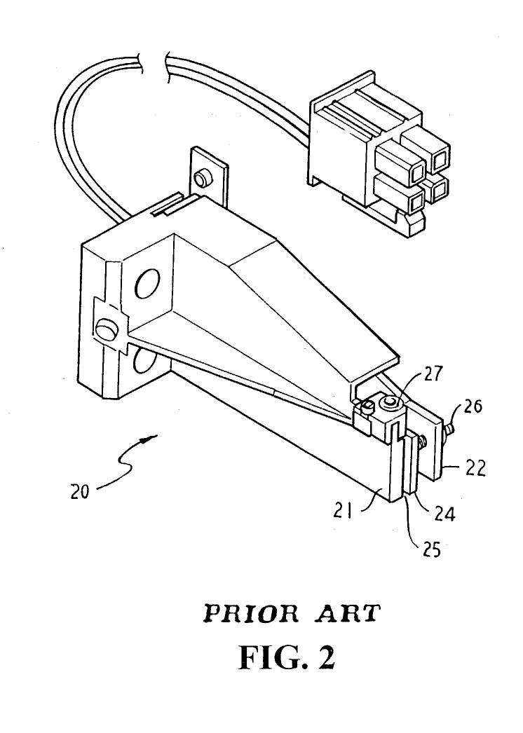

FIG. 3 is the front view of the conventional wire clip.

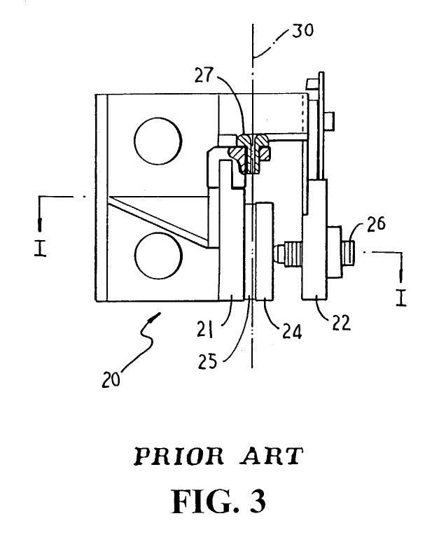

FIG. 4 is a sectional view along I-I of FIG. 3.

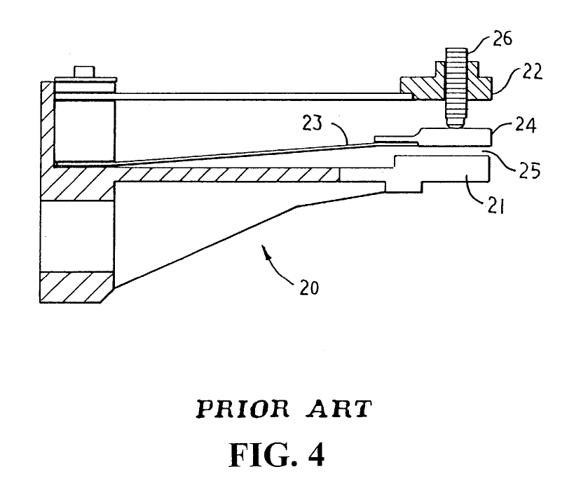

FIG. 5 is a sectional view of another conventional wire clip.

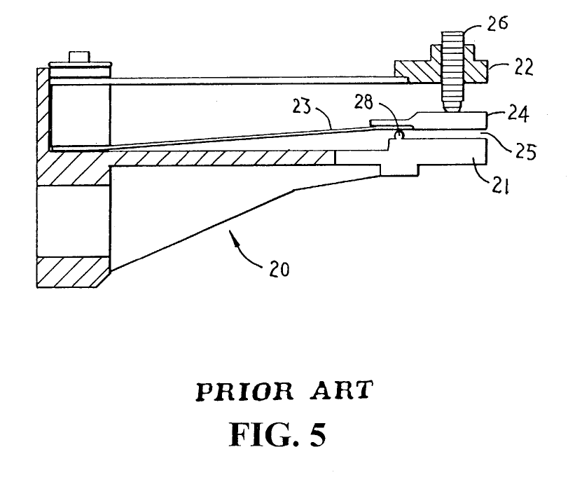

FIG. 6 is a perspective view of a wire clip of the present invention.

FIG. 7 is the front view of the wire clip in accordance with the present invention.

FIG. 8 is a sectional view along II-II of FIG. 7 in accordance with the present invention.

### DETAILED DESCRIPTION OF THE PRESENT INVENTION

The following descriptions are of exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

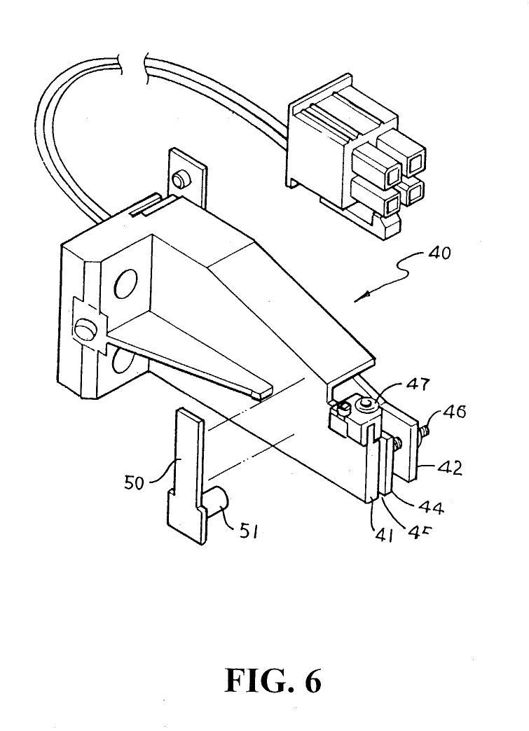

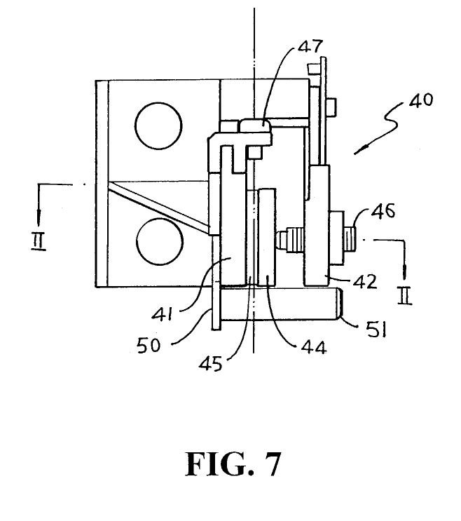

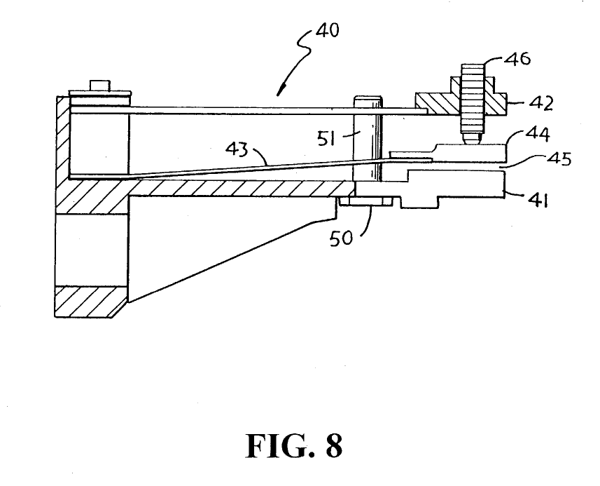

Referring to FIGS. 6, 7 and 8, there is shown a wire clip for integrated circuit comprising a main body 40 having a front end provided with a front wall 41 and the rear wall 42. A spring plate 43 elastically extended toward the rear wall 42 is provided between the front wall 41 and the rear wall 42. The front end of the spring plate 43 is provided with an abrasion-resistant plate 44 such that a passage 45 is formed between the abrasion-resistant plate 44 and the front wall 41. The rear wall 42 is provided with an adjusting bolt 46. The rotating of the adjusting bolt 46 urges the abrasion-resistant plate 44 so as to change the gap of the passage 45. The top of the passage 45 is provided with a wire mount 47 such that the metallic wire 30 passes through the wire mount 47 and the passage 45. A soldering gun melts the metallic wire 30 and the wire 30 is soldered onto the predetermined position. In accordance with the present invention, the front wall 41 of the main body 40 having one end is mounted with a connection plate 50, and the bottom edge of the connection plate 50 is provided with a blocking shaft 51 such that the blocking shaft 51 transversely crosses the bottom of the rear side of the passage 45.

In accordance with the present invention, when the metallic wire 30 passes through the wire mount 47 and the passage 45, due to the fact that the blocking shaft 51 transversely crosses the bottom of the rear side of the passage 45, the metallic wire 30 is restricted to the range of the passage 45 by the blocking shaft 51. That is, even when the body 40, in the course of operation, is moved intermittently or rapidly to pull the metallic wire 30, the metallic wire 30 will be restricted at the range of the passage 45 between the abrasion-resistant plate 44 and the front wall 41, and thus, the wire-entangling situation will not be occurred.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

We claim:

1. An improved structure of a wire clip for integrated circuit having a main body with the front end thereof being provided with a front wall and a rear wall, a spring plate elastically extended toward the rear wall being provided between the front wall and the rear wall, the front end of the spring plate being provided with an abrasion-resistant such that a passage is formed between the abrasion-resistant plate and the front wall, and the rear wall being provided with an adjusting bolt, and the top of the passage being provided with a wire mount, and the metallic wire passed through the wire mount and the passage, characterized in that the front wall of the main body having one end is mounted with a connection plate, and the bottom edge of the connection plate is provided with a blocking shaft such that the blocking shaft transversely crosses the bottom of the rear side of the passage.
